(19) United States
(12) Patent Application Publication
(10) Pub. No.: US 2025/0316866 A1
(43) Pub. Date: Oct. 9, 2025

(54) BATTERY PACK

(71) Applicant: SAMSUNG SDI CO., LTD., Yongin-si (KR)

(72) Inventor: Sangdo HUR, Yongin-si (KR)

(21) Appl. No.: 19/093,442

(22) Filed: Mar. 28, 2025

(30) Foreign Application Priority Data
Apr. 5, 2024 (KR) 10-2024-0046953

(51) Int. Cl. H01M 50/595; H01M 50/287; H01M 50/588

(52) U.S. Cl. CPC H01M 50/595; H01M 50/287; H01M 50/588

(57) ABSTRACT

A battery pack includes a battery cell including a first main surface and a second main surface facing each other, a circuit unit on an upper surface of the battery cell, the upper surface of the battery cell connecting the first main surface and the second main surface of the battery cell to each other, and an insulating tape extending from the first main surface to the second main surface of the battery cell while surrounding the circuit unit, the insulating tape including a first region and a second region having different adhesive strengths from each other.

### CROSS-REFERENCE TO RELATED APPLICATION

The present application claims priority and the benefit of Korean Patent Application No. 10-2024-0046953, filed on Apr. 5, 2024, in the Korean Intellectual Property Office, the disclosure of which is incorporated herein by reference in its entirety.

### BACKGROUND

### 1. Field

One or more embodiments relate to a battery pack.

### 2. Description of the Related Art

In general, secondary batteries can be charged and discharged, unlike primary batteries that cannot be charged. Secondary batteries are used as energy sources for mobile devices, electric vehicles, hybrid vehicles, electric bicycles, uninterruptible power supplies, etc. Also, depending on the type of external devices to which the secondary batteries are applied, the secondary batteries may be used in the form of a single secondary battery or a pack in which a plurality of secondary batteries are connected and bundled into a single unit.

A small mobile device, such as a mobile phone, may operate for a certain period of time with only the output and capacity of a single secondary battery. However, when use for a long period of time and high power are required, such as in a large-sized mobile device that includes a laptop or an electric vehicle or hybrid vehicle that consumes a lot of power, a pack type including a plurality of secondary batteries is preferred due to the output and capacity thereof. Also, the output voltage or output current may be increased according to the number of secondary batteries embedded therein.

### SUMMARY

According to one or more embodiments, a battery pack includes a battery cell including a first main surface and a second main surface facing each other, a circuit unit on an upper surface of the battery cell, the upper surface of the battery cell connecting the first main surface and the second main surface of the battery cell to each other, and an insulating tape extending from the first main surface to the second main surface of the battery cell while surrounding the circuit unit, the insulating tape including a first region and a second region having different adhesive strengths from each other.

The first region of the insulating tape may have a stronger adhesive strength than the second region of the insulating tape.

The insulating tape may include a tape substrate defining a common base supporting the first region and the second region of the insulating tape, and an adhesive layer on an inner surface of the tape substrate, the first region of the insulating tape may include a first portion of the tape substrate and the adhesive layer, and the second region of the insulating tape may include a second portion of the tape substrate without the adhesive layer.

The second region of the insulating tape may be on a peripheral region of the insulating tape.

The second region of the insulating tape may include a first sub-region on the peripheral region of the insulating tape, and a second sub-region on an isolated inner region of the insulating tape, the second sub-region being spaced apart from the peripheral region of the insulating tape, and the first region of the insulating tape may be on an inner region of the insulating tape connected to the peripheral region of the insulating tape.

The insulating tape may include a tape substrate defining a common base supporting the first region and the second region of the insulating tape, and an adhesive layer on an inner surface of the tape substrate, the first region of the insulating tape may include a first portion of the tape substrate and the adhesive layer on the inner surface of the tape substrate, and the first sub-region and the second sub-region of the second region of the insulating tape may have a same shape and including a second portion of the tape substrate without the adhesive.

The insulating tape may include a tape substrate defining a common base supporting the first region and the second region of the insulating tape, and an adhesive layer on an inner surface of the tape substrate, the first region of the insulating tape may include a first portion of the tape substrate and the adhesive layer on the inner surface of the tape substrate, and the first sub-region and the second sub-region of the second region of the insulating tape may have different shapes from each other.

The first sub-region of the second region of the insulating tape may include a second portion of the tape substrate without the adhesive layer, and the second sub-region of the second region of the insulating tape may include a coating material covering the adhesive layer to remove adhesiveness.

The first region of the insulating tape may be on the inner region of the insulating tape surrounding the second sub-region of the second region of the insulating tape, the first region being connected to the peripheral region of the insulating tape.

The insulating tape may further include a cutting line along an outer edge thereof, the cutting line extending along the peripheral region of the insulating tape that includes the first sub-region of the second region of the insulating tape.

The cutting line may be formed by laser cutting.

The insulating tape may include a tape substrate and an adhesive layer on an inner surface of the tape substrate, the adhesive layer being spaced apart from the cutting line by a width of the first sub-region of the second region.

The first sub-region of the second region of the insulating tape may extend along an entirety of the peripheral region of the insulating tape, the first sub region surrounding an entire outline of the insulating tape.

The battery cell may further include a terrace defining a mounting space, the circuit unit being mounted on the mounting space of the terrace, on a basis of a direction in which the first and second main surfaces of the battery cell face each other, the first main surface may be located at a position relatively close to the terrace and the second main surface is located at a position relatively far from the terrace, and the first sub-region of the second region of the insulating tape may be at least on a portion of the peripheral region of the insulating tape that is attached to the second main surface of the battery cell.

The first sub-region of the second region may not be on a portion of the peripheral region of the insulating tape that is attached to the first main surface, the terrace, or the circuit unit.

The insulating tape may extend in a direction of connection of the first main surface or the terrace at a position relatively close to the first main surface to the second main surface, while bypassing the circuit unit to surround the circuit unit.

The insulating tape may include a first width covering the terrace on the first main surface, and a second width covering the second main surface, the first width being larger than the second width.

The circuit unit may include a circuit board and an input/output wire drawn from the circuit board to an outside of the circuit board, and the input/output wire may extend beyond the circuit board at a position outside the second width of the insulating tape covering the circuit board on the second main surface of the battery cell, the input/output wire not contacting the insulating tape.

The circuit unit may include a circuit board and an integrated circuit chip on the circuit board, the second sub-region of the second region of the insulating tape being at a position corresponding to the integrated circuit chip.

### BRIEF DESCRIPTION OF THE DRAWINGS

Features will become apparent to those of skill in the art by describing in detail exemplary embodiments with reference to the attached drawings, in which:

FIG. 1 is a perspective view of a battery pack according to embodiments of the present disclosure and shows a second main surface of a battery cell;

FIG. 2 is an exploded perspective view of the battery pack of FIG. 1;

FIG. 3 is a plan view of the second main surface of the battery pack of FIG. 1;

FIG. 4 is a plan view of a first main surface of the battery pack of FIG.;

FIG. 5A is a plan view of an insulating tape of FIG. 1 in an unfolded state;

FIG. 5B is a plan view of an insulating tape according to other embodiments;

FIG. 5C is a plan view of an insulating tape according to yet other embodiments;

FIG. 6 is a cross-sectional view of the insulating tape along line VI-VI of FIG. 5A;

FIG. 7 is an exploded perspective view of the insulating tape of FIG. 5A;

FIG. 8 is a diagram showing an adhesive not exposed via a tape substrate that is cut by laser cutting of an insulating tape, according to embodiments of the present disclosure; and

FIG. 9 is a diagram of a battery pack mounted in a set device, according to embodiments of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Expressions such as “at least one of,” if preceding a list of elements, modify the entire list of elements and do not modify the individual elements of the list.

Hereinafter, a battery pack according to embodiments of the present disclosure is described with reference to the accompanying drawings.

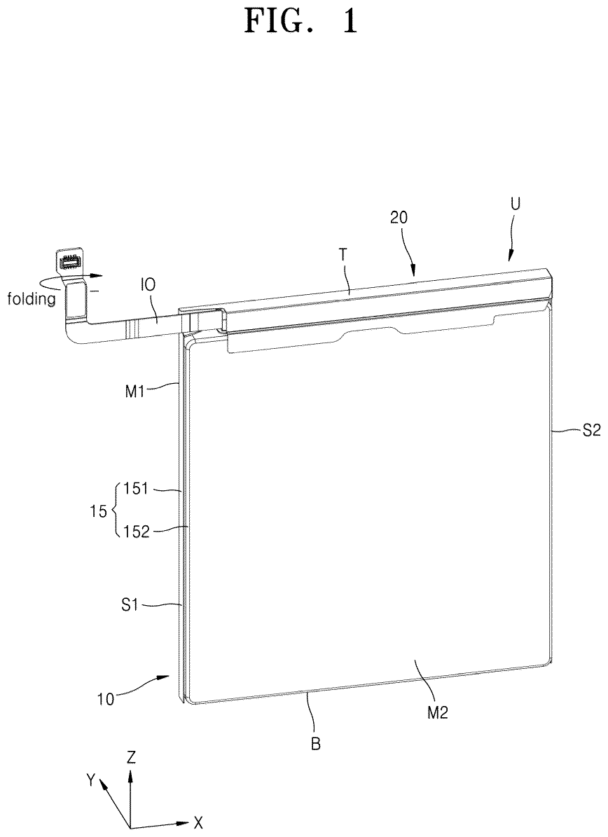

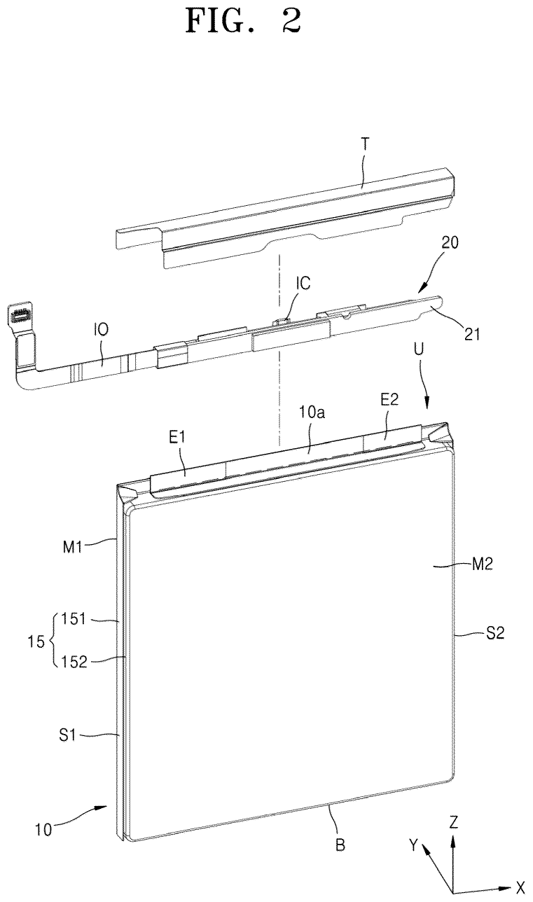

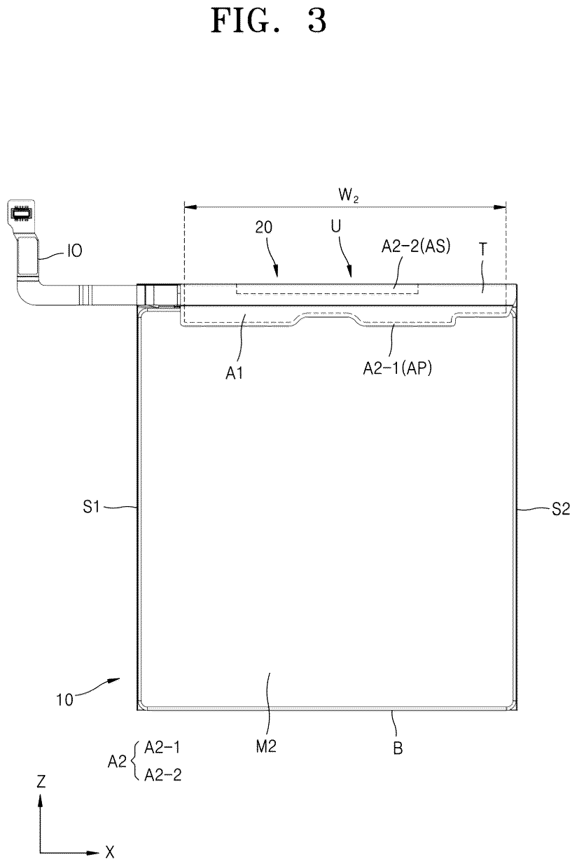

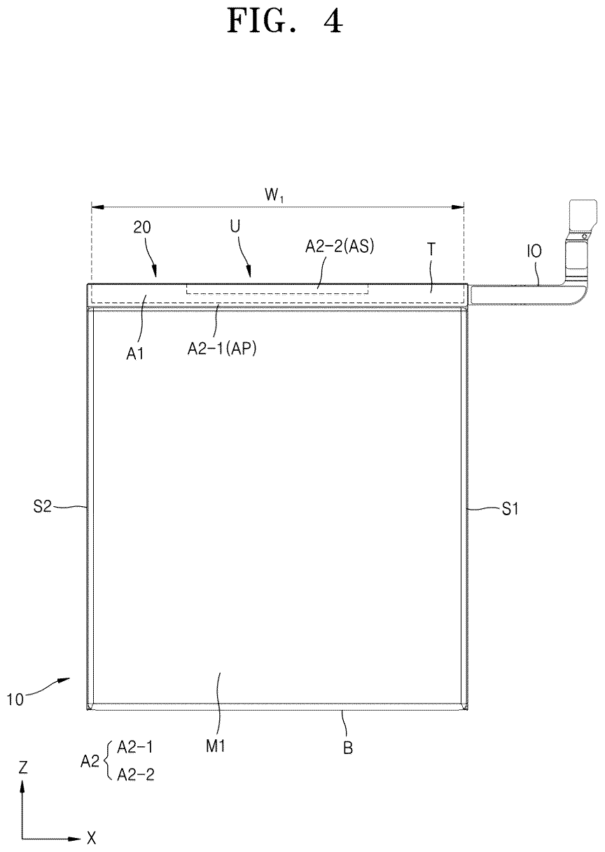

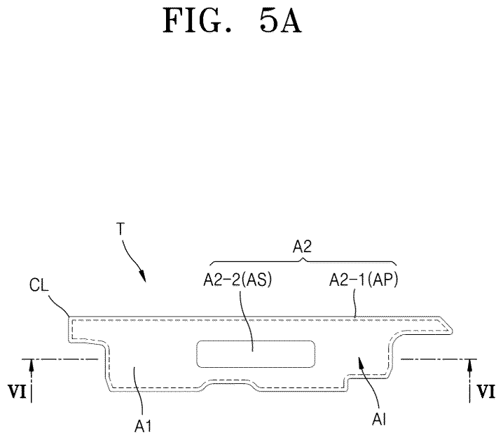

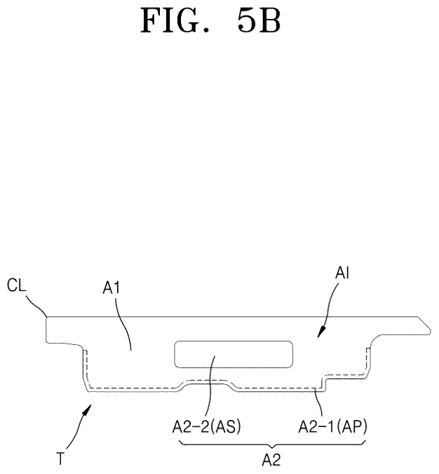

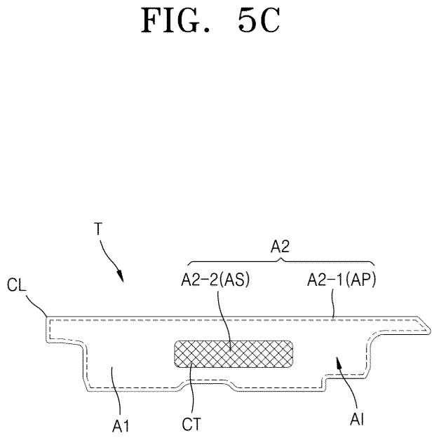

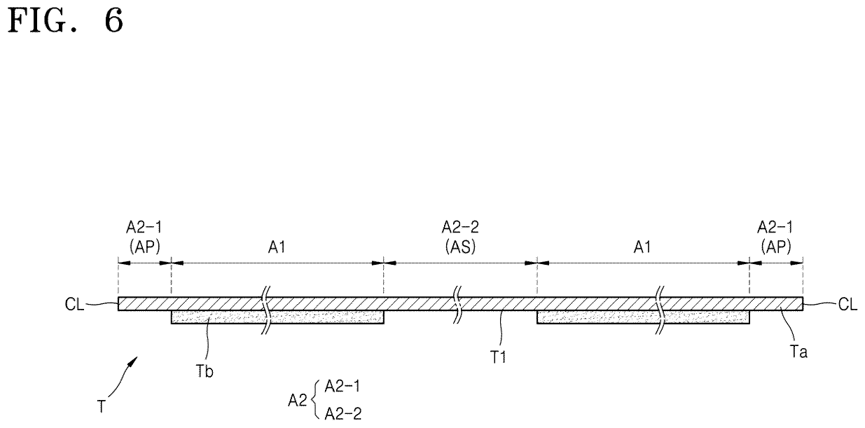

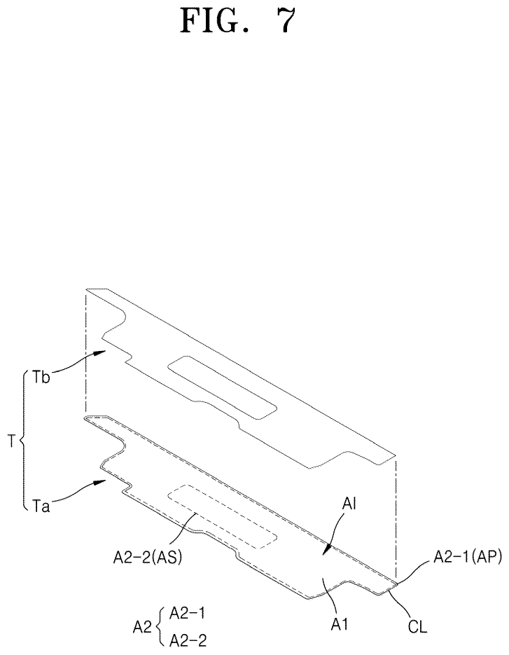

FIG. 1 is a perspective view of a battery pack according to embodiments of the present disclosure and shows a second main surface M2 of a battery cell 10. FIG. 2 is an exploded perspective view of the battery pack of FIG. 1. FIG. 3 is a plan view showing the second main surface M2 of the battery pack of FIG. 1. FIG. 4 is a plan view showing a first main surface of the battery pack of FIG. 1. FIG. 5A is a plan view of an insulating tape of FIG. 1 in an unfolded state. FIG. 6 is a cross-sectional view of the insulating tape along line VI-VI of FIG. 5A. FIG. 7 is an exploded perspective view of the insulating tape of FIG. 5A.

Referring to FIGS. 1 and 2, a battery pack according to embodiments of the present disclosure may include a battery cell 10 including first and second main surfaces M1 and M2 facing each other, a circuit unit 20 disposed on an upper surface U of the battery cell 10, wherein the upper surface U of the battery cell 10 connects the first and second main surfaces M1 and M2 of the battery cell 10 to each other, and an insulating tape T extending in a direction of connection of the first and second main surfaces M1 and M2 of the battery cell 10 while bypassing the circuit unit 20 to surround the circuit unit 20. Referring to FIGS. 3-5A, the insulating tape T may include first and second regions A1 and A2 having different adhesive strengths. For example, the insulating tape T may include the first region A1 having relatively strong adhesive strength and the second region A2 having relatively weak adhesive strength or no adhesion (e.g., the first region A1 may have a stronger adhesive strength than the second region A2).

In embodiments of the present disclosure, referring to FIGS. 1 and 2, the battery cell 10 may include the pair of first and second main surfaces M1 and M2 facing each other, the upper surface U and a bottom surface B facing each other and connecting the pair of first and second main surfaces M1 and M2 to each other, and a pair of first and second side surfaces S1 and S2 facing each other and connecting the pair of first and second main surfaces M1 and M2 to each other. For example, in embodiments of the present disclosure, an electrode surface (i.e., the upper surface U of the battery cell 10) and the bottom surface B of the battery cell 10, and the pair of first and second side surfaces S1 and S2 of the battery cell 10 may face each other in directions intersecting with each other. It is noted that in the figures, an undescribed Y-axis indicates a facing direction between the first main surface M1 and the second main surface M2 of the battery cell 10, and an undescribed Z-axis indicates a facing direction between the upper surface U and the bottom surface B of the battery cell 10.

In embodiments of the present disclosure, referring to FIG. 2, a pair of different electrodes (i.e., a first electrode E1 and a second electrode E2) forming charging and discharging paths of the battery cell 10 may be disposed on the electrode surface of the battery cell 10 (i.e., on the upper surface U of the battery cell 10), and the circuit unit 20 for establishing an electrical connection with the first and second electrodes E1 and E2 of the battery cell 10 may be disposed on the electrode surface of the battery cell 10. In embodiments of the present disclosure, the circuit unit 20 may include a switch element for controlling the charging and discharging of the battery cell 10 while forming the charging and discharging paths for the battery cell 10 using the electrical connection with the first and second electrodes E1 and E2 of the battery cell 10 or include an integrated circuit chip IC (e.g., a safety element) for stopping the charging and discharging of the battery cell 10 in abnormal situations (e.g., during overheating, overcharging, and/or overdischarging).

Also, the circuit unit 20 may include an input/output wire IO for establishing an electrical connection between the battery cell 10 and an external device, e.g., an external load or an external charger. For example, in embodiments of the present disclosure, a signal path for signals (e.g., a charging or discharging current, a measurement signal, and/or a control signal) may be formed between the battery cell 10 and an external device via the input/output wire IO. For example, in embodiments of the present disclosure, the circuit unit 20 electrically connected to the first and second electrodes E1 and E2 of the battery cell 10 may include a circuit board 21 and the integrated circuit chip IC mounted on the circuit board 21. Also, the circuit unit 20 may include the input/output wire IO extending from an electrical connection with the circuit board 21. For example, in embodiments of the present disclosure, the circuit board 21 may be formed as a relatively hard, rigid circuit board. Also, the input/output wire IO may be formed as a relatively soft, flexible circuit board.

In embodiments of the present disclosure, the insulating tape T attached to the circuit unit 20 across the electrode surface (or corresponding to the upper surface U) of the battery cell 10 may electrically insulate at least a portion of the circuit unit 20 from the surrounding environment around the battery cell 10 and may physically protect at least a portion of the circuit unit 20 from the surrounding environment around the battery cell 10. Also, throughout this specification, the feature, in which the insulating tape T extends across the upper surface U of the battery cell 10 or the circuit unit 20 disposed on the upper surface U of the battery cell 10 may indicate that the insulating tape T extends across at least a portion of the upper surface U of the battery cell 10 or at least a portion of the circuit unit 20 disposed on the upper surface U of the battery cell 10. For example, this feature may indicate that the insulating tape T surrounds a portion of the input/output wire IO extending from the upper surface U of the battery cell 10 to an external location beyond the upper surface U of the battery cell 10, rather than entirely surrounding all of the circuit board 21 forming the circuit unit 20, the integrated circuit chip IC mounted on the circuit board 21, and the input/output wire IO extending from the connection of the circuit board 21.

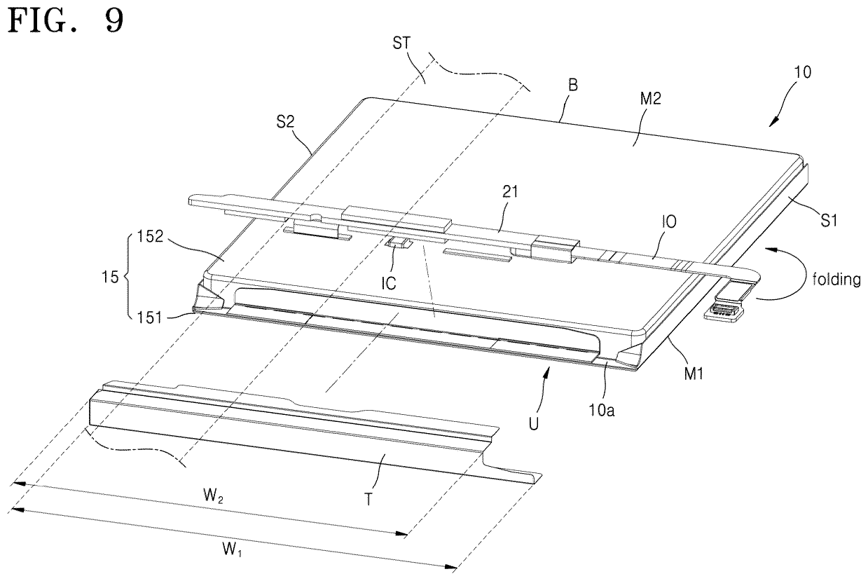

In embodiments of the present disclosure, considering that the input/output wire IO may be formed as a relatively soft, flexible circuit board and surrounded by an insulating coating to ensure electrical insulation, the input/output wire IO may be exposed via the insulating tape T. For example, the battery pack according to embodiments of the present disclosure may be mounted on a set device that uses the battery pack as a driving power source. Also, the battery pack may be mounted in the set device such that the first main surface M1 of the battery cell 10 or a terrace 10a of the battery cell 10 relatively close to the first main surface M1 is at a lower position and the second main surface M2 of the battery cell 10 is at a higher position (e.g., the first main surface M1 may be coplanar and coextensive with the terrace 10a to define a surface below the second main surface M2, as shown in FIG. 9). The input/output wire IO may be connected to a connection terminal of the set device while folding and unfolding relative to the second main surface M2 above which a free space is secured (e.g., the input/output wire IO may be folded toward the second main surface M2 or unfolded away from the second main surface M2, as shown in FIG. 9).

Referring to FIGS. 3-4, the insulating tape T may have a portion having a first width W₁ (e.g., in the X-axis direction) and attached to the first main surface M1 of the battery cell 10 or the terrace 10a relatively close to the first main surface M1, and a portion having a second width W₂ (e.g. in the X-axis direction) and attached to the second main surface M2 of the battery cell 10. Also, the first width W₁ of the insulating tape T formed on the first main surface M1 may be different from the second width W₂ of the insulating tape T formed on the second main surface M2 (e.g., the first width W₁ may be larger than the second width W₂).

Therefore, even if the input/output wire IO folds toward the second main surface M2 of the battery cell 10, the input/output wire IO may be prevented from being attached to the insulating tape T (i.e., to a portion of the insulating tape T having the second width W₂ which is formed relatively short on the second main surface M2). For example, the input/output wire IO may separate from the circuit board 21 or extend beyond the circuit board 21 at a position outside the second width W₂ of the insulating tape T covering the circuit board 21 on the second main surface M2 of the battery cell 10, so that the input/output wire IO is not in contact (e.g., direct contact) with the insulating tape T. Even if the input/output wire IO located outside the circuit board 21 folds toward the second main surface M2 of the battery cell 10, unintentional contact or adhesion between the input/output wire IO and the insulating tape T may be prevented.

Referring to FIG. 6, in embodiments of the present disclosure, the insulating tape T may include an adhesive Tb on an inner surface T1 of the insulating tape T facing the battery cell 10 so as to provide adhesion to the upper surface U of the battery cell 10 or the circuit unit 20 disposed on the upper surface U of the battery cell 10. For example, the insulating tape T may include a tape substrate Ta and the adhesive Tb formed on the inner surface T1 of the tape substrate Ta. For example, referring to FIG. 7, the shape of the adhesive Tb may be that of the first region A1.

In embodiments of the present disclosure, referring to FIG. 5A, the insulating tape T may have different regions with different adhesive strengths between the upper surface U of the battery cell 10 and the circuit unit 20 on the upper surface U of the battery cell 10. For example, the insulating tape T may include the first region A1 having relatively strong adhesive strength and the second region A2 having relatively weak adhesive strength or no adhesion. For example, in embodiments of the present disclosure, the insulating tape T may include a first sub-region A2-1 of the second region A2 and a second sub-region A2-2 of the second region A2, which are formed in a peripheral region AP of the insulating tape T and an inner region AI of the insulating tape T, respectively. Throughout this specification, the inner region AI of the insulating tape T may represent a region surrounded by the peripheral region AP of the insulating tape T. For example, the peripheral region AP of the insulating tape T may be formed along a profile line that forms the outline (e.g., perimeter) of the insulating tape T (e.g., the peripheral region AP may be formed along an outermost edge of the insulating tape T or along a cutting line CL, and may be separated from the inner region AI in FIGS. 3-5A by a dashed line). The peripheral region AP of the insulating tape T may further include a region that is shifted into the insulating tape T from the profile line (or the cutting line CL) forming the boundary of the insulating tape T.

For example, in embodiments of the present disclosure, the peripheral region AP of the insulating tape T may have a region shifted into the insulating tape T in a rim shape so as to form a certain width toward the inside of the insulating tape T along the profile line (or the cutting line CL) forming the boundary of the insulating tape T. For example, in embodiments of the present disclosure, the first sub-region A2-1 of the second region A2 of the insulating tape T may include a region formed along the peripheral region AP of the insulating tape T having weak adhesive strength or no adhesion. For example, in embodiments of the present disclosure, the first sub-region A2-1 of the second region A2 of the insulating tape T may correspond to the peripheral region AP of the insulating tape T and may have relatively weak adhesive strength or no adhesion. In this sense, in embodiments of the present disclosure, the first sub-region A2-1 of the second region A2 may not be formed entirely along the peripheral region AP of the insulating tape T. For example, the first sub-region region A2-1 of the second region A2 may be formed at least partially along the peripheral region AP of the insulating tape T.

In embodiments of the present disclosure, the inner region AI of the insulating tape T may represent a region surrounded by the peripheral region AP of the insulating tape T. In embodiments of the present disclosure, the inner region AI may include the second sub-region A2-2 of the second region A2 of the insulating tape T having relatively weak adhesive strength or no adhesion that may be represented by an isolated inner region AS formed in an isolated shape in the inner region AI surrounded by the peripheral region AP (e.g., the second sub-region A2-2 may be represented by the isolated inner region AS that is formed within the inner region AI). Also, the feature, in which the second sub-region A2-2 of the second region A2 of the insulating tape T having weak adhesive strength or no adhesion is formed in the isolated inner region AS in the inner region AI of the insulating tape T, may indicate that the inner region AI having a shape isolated from the peripheral region AP of the insulating tape T and spaced apart from the peripheral region AP like an island to form the second sub-region A2-2 is formed in the isolated inner region AS that is not connected to the outside of the inner region AI. For example, in embodiments of the present disclosure, the inner region AI of the insulating tape T surrounded by the peripheral region AP of the insulating tape T may include the inner region AI connected to the peripheral region AP and the isolated inner region AS separated from the peripheral region AP. In embodiments of the present disclosure, the inner region AI formed as the second sub-region A2-2 of the second region A2 of the insulating tape T having weak adhesive strength or no adhesion may represent the isolated inner region AS separated from the peripheral region AP.

In embodiments of the present disclosure, the first region A1 of the insulating tape T having relatively strong adhesive strength may be formed in the inner region AI of the insulating tape T connected to the peripheral region AP of the insulating tape T. For example, the first region A1 may be formed in the inner region AI connected to the peripheral region AP formed as the first sub-region A2-1 of the second region A2. For example, in embodiments of the present disclosure, the first region A1 of the insulating tape T having relatively strong adhesive strength may be connected to the peripheral region AP of the insulating tape T in which the first sub-region A2-1 is formed, while surrounding the second sub-region A2-2 of the insulating tape T, which is isolated and spaced apart from the peripheral region AP in which the first sub-region A2-1 is formed. For example, referring to FIG. 5A, the second sub-region A2-2 (weak or no adhesive) may have an isolated island shape, and may be surrounded (e.g., completely surrounded in a top view) by the first region A1 (strong adhesive), which, in turn, may be surrounded (e.g., completely surrounded) by the first sub-region A2-1 (weak or no adhesive).

For example, in embodiments of the present disclosure, in a direction inward from the peripheral region AP of the insulating tape T (i.e., in a direction oriented from an outermost edge of the insulating tape T toward the center of the insulating tape T), the insulating tape T may include the first sub-region A2-1 formed in the peripheral region AP, the first region A1 connected to the peripheral region AP, and the second sub-region A2-2 spaced apart from the peripheral region AP with the first region A1 therebetween. Compared to the first region A1 of the insulating tape T having relatively strong adhesive strength, the first sub-region A2-1 and the second sub-region A2-2 of the insulating tape T may be formed in the second region A2 of the insulating tape T having relatively weak adhesive strength or no adhesion. For example, the first sub-region A2-1 and the second sub-region A2-2 of the second region A2 may have equally weak adhesion strengths or may not have any adhesion. In another example, one of the first sub-region A2-1 and the second sub-region A2-2 of the second region A2 may have weak adhesive strength and the other may not have adhesion.

In embodiments of the present disclosure, the first sub-region A2-1 and the second sub-region A2-2 of the insulating tape T may be formed in the second region A2 of the insulating tape T from which adhesion is removed. The occurrence of adhesion that causes unnecessary physical interference with other components may be prevented because neither of these first sub-region A2-1 and the second sub-region A2-2 have the adhesion.

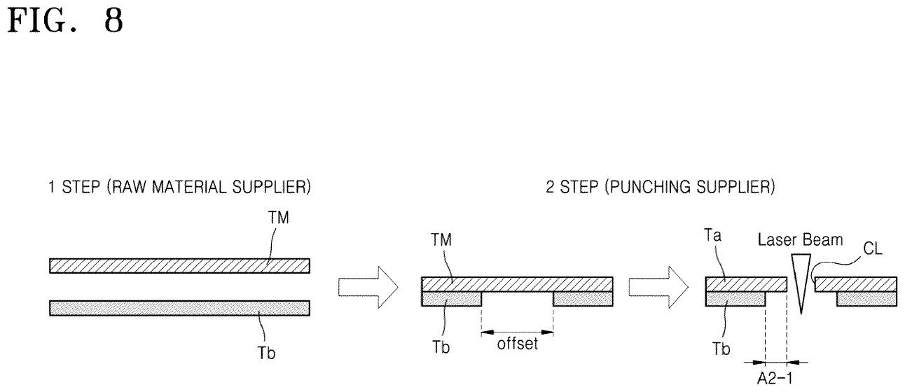

FIG. 8 is a diagram showing that an adhesive is not exposed via a tape substrate that is cut by laser cutting of an insulating tape on which a first sub-region is formed. FIG. 9 is a diagram of a battery pack mounted in a set device, according to embodiments of the present disclosure, and shows traverse of a set tape extending across the insulating tape T of the battery pack.

Referring to FIGS. 1, 2, 5A, and 9, in embodiments of the present disclosure, the first sub-region A2-1 of the insulating tape T may have no adhesion, and may prevent unnecessary adhesion with a set wire ST (see FIG. 9) of a set device extending across the insulating tape T (e.g., unnecessary adhesion due to an adhesive exposed by cutting a raw material (a laminate of a tape base material TM and the adhesive Tb in FIG. 8) of the insulating tape T).

In a comparative example of the present disclosure, if a region with a weak adhesive (or no adhesive) were not formed on an insulating tape (e.g., if the insulating tape T did not include the first sub-region with weak/no adhesive), the insulating tape would have been formed as a laminate of a tape base material with a continuous adhesive layer on the entire tape base material. As such, during laser cutting (laser beam) of the laminate (e.g., to separate one continuous laminate into multiple individual insulating tapes), the tape base material could have heat-shrunk (e.g., the heat could have caused the tape base material to contract and expose a top of the adhesive layer underneath) or separated from the laminate, thereby exposing the adhesive layer. For example, if such an insulating tape with an exposed adhesive layer were to be applied to a battery pack, an unnecessary adhesion would have occurred between the set wire ST (see FIG. 9) and the insulating tape with the exposed adhesive. Such unnecessary adhesion may disturb the trajectory of the set wire ST connecting the battery pack to a set device or cause adhesion noise by repeated attachment to and detachment from the set wire ST.

For example, referring to FIG. 9, the battery pack according to embodiments of the present disclosure may be installed in the set device that receives driving power from the battery pack and may be connected to the set wire ST for establishing an electrical connection with the set device. The battery pack may communicate charge and discharge currents or control signals for controlling driving of the battery pack with the set device via the electrical connection with the set wire ST extending across the battery pack.

For example, if the set wire ST were to extend across an insulating tape with an exposed adhesive layer while extending across the battery pack, the set wire ST would have caused physical interference with the exposed adhesive leaking around the insulating tape. Also, the adhesive leaking around the insulating tape could have resulted in separating the insulating tape from the raw material (e.g., separating the laminate into the tape base material and the adhesive) along the shape of the insulating tape.

In contrast, according to embodiments of the present disclosure shown in FIG. 8, the insulating tape T may include a tape base material TM and an adhesive Tb formed on the tape base material TM, as a raw material (i.e., a laminate of the tape base material TM and the adhesive Tb). Separate individual portions of the insulating tape T may be formed by a cutting operation of cutting and separating the insulating tape T into separate individual portions along a length of the insulating tape T. For example, the insulating tape T may be cut by irradiation of laser beams. A heat shrinkage of the tape base material TM may potentially occur depending on the heat energy supplied by the irradiation of laser beams. In embodiments of the present disclosure, since the first sub-region A2-1 of the second region A2 may be without the adhesive Tb along the peripheral region AP of the insulating tape T, even if heat shrinkage of the tape base material TM occurs, exposure of the adhesive Tb through the heat-shrunk tape base material TM may be prevented or substantially minimized (e.g., since the edge of the tape base material TM includes no adhesive or very little adhesive). The adhesive Tb may retreat (e.g., may be partially removed), by the width of the first sub-region A2-1, from the cutting line CL of the resultant tape substrate Ta divided through an offset without the adhesive Tb between regions to be formed having different tape substrates Ta and the irradiation position of the laser beam for dividing the tape base material TM into different tape substrates Ta. As shown in FIG. 8, the adhesive Tb may not be exposed from the cutting line CL of the resultant cut tape substrate Ta.

For example, in embodiments of the present disclosure, the width of the first sub-region A2-1 may remain as long as the width excluding the width that is heat-shrunk by the laser cutting of the insulating tape T. For example, in embodiments of the present disclosure, the width of the first sub-region A2-1 may not remain as long as the width that is heat-shrunk by the laser cutting of the insulating tape T. However, in embodiments of the present disclosure, the width of the first sub-region A2-1 may be designed to have a sufficient width by considering the processing tolerance of laser cutting. For example, the first sub-region A2-1 may be formed with a certain width along the peripheral region AP of the insulating tape T.

FIG. 5B is a plan view of an insulating tape that may be applied to a battery pack according to embodiments of the present disclosure and shows the insulating tape in an unfolded state. For example, FIG. 5B is a plan view of an insulating tape according to modified embodiments of the insulating tape of FIG. 5A.

For example, in embodiments of the present disclosure shown in FIG. 5A, the first sub-region A2-1 of the insulating tape T may be formed (e.g., continuously) along an entirety of the peripheral region AP of the insulating tape T. In another example, the first sub-region A2-1 may be formed only in a portion of the peripheral region AP of the insulating tape T. In yet another example, as shown in FIG. 5B, the first sub-region A2-1 of the insulating tape T may be formed along the peripheral region AP of the insulating tape T extending onto the first and second main surfaces M1 and M2 of the battery cell 10 on the peripheral region AP of the insulating tape T.

Referring to FIG. 2, in the battery pack according to embodiments of the present disclosure, the terrace 10a may be located at a position close to the first main surface M1 among the first and second main surfaces M1 and M2 and may be located at a position far from the second main surface M2 among the first and second main surfaces M1 and M2, in a direction in which the first and second main surfaces M1 and M2 face each other. In embodiments of the present disclosure, the terrace 10a may extend from the first main surface M1 of the battery cell 10 so that the terrace 10a forms substantially the same plane as the first main surface M1 in the direction in which the first and second main surfaces M1 and M2 of the battery cell 10 face each other and may be located in a stepped region from the second main surface M2.

In embodiments of the present disclosure, as a core forming the battery cell 10, the terrace 10a may be formed as a sealing portion of an exterior material 15 surrounding an electrode assembly. The terrace 10a may form the sealing portion that couples first and second exterior materials 151 and 152 to each other, which face each other with the electrode assembly therebetween. The terrace 10a may provide a mounting space for the circuit unit 20, and the circuit unit 20 may be mounted on the terrace 10a. In embodiments of the present disclosure, the circuit unit 20 mounted on the terrace 10a may be accommodated in the mounting space inside the set device such that the circuit unit 20 is at a higher position and the terrace 10a is at a lower position so as to establish an electrical connection with the set device. For example, the set wire ST (see FIG. 9) may extend, above the battery pack accommodated in the mounting space of the set device, across the circuit unit 20 at a higher position. For example, the set wire ST formed as a flexible circuit board, such as a flexible printed circuit (FPC), may extend.

If an insulating tape were to be formed without the first sub-region A2-1, the set wire ST could have been adhered to the circuit unit 20 due to the adhesive Tb (see FIG. 6) leaking from the insulating tape covering the circuit unit 20, which would have disturbed the trajectory of the set wire ST. For example, adhesion noise would have been generated as the insulating tape and the set wire ST would have been repeatedly attached to and detached from each other.

In contrast, in embodiments of the present disclosure, the first sub-region A2-1 having relatively weak adhesive strength or no adhesive may be formed along the peripheral region AP of the insulating tape T. Even if heat shrinkage of the tape base material TM (or the tape substrate Ta cut from the tape base material TM) occurs due to irradiation of laser beams for cutting the insulating tape T from the tape base material TM corresponding to the raw material of the insulating tape T (the laminate of the tape base material TM and the adhesive Tb, see FIG. 8), the adhesive Tb may be prevented from being exposed from the heat-shrunk tape base material TM (or the tape substrate Ta cut from the tape base material TM, see FIG. 8) by arranging the adhesive Tb that retreats, by the width of the first sub-region A2-1, from the irradiation position of the laser beam. In embodiments of the present disclosure, the first sub-region A2-1 having weak adhesive strength or no adhesive may be formed along the peripheral region AP of the insulating tape T. For example, the first sub-region of the insulating tape T may be formed entirely along the peripheral region AP of the insulating tape T. In embodiments of the present disclosure, the first sub-region A2-1 having weak adhesive strength or no adhesion may be formed along the peripheral region AP of the insulating tape T located on the second main surface M2, in which physical interference with the set wire ST (see FIG. 9) is possible, in the peripheral region AP of the insulating tape T.

As shown in FIG. 9, if the battery pack is arranged such that the terrace 10a of the battery pack is at a lower position and the circuit unit 20 of the battery pack is at a higher position (e.g., if the battery pack is arranged such that the first main surface M1 of the battery cells 10 forming the battery pack is at a lower position and the second main surface M2 of the battery cell 10 is at a higher position), the first sub-region A2-1 having weak adhesive strength or no adhesion may be formed along the peripheral region AP of the insulating tape T located on the second main surface M2 providing a free space in which the set wire ST (see FIG. 9) may extend. In embodiments of the present disclosure, the feature, in which the battery pack is arranged such that the terrace 10a of the battery pack is at a lower position and the circuit unit 20 of the battery pack is at a higher position, may indicate that the battery pack is arranged such that the first main surface M1 of the battery cell 10 close to the terrace 10a of the battery pack is at a lower position and the second main surface M2 of the battery cell 10 far from the terrace 10a of the battery pack is at a higher position (e.g., the first main surface M1 may be between a surface supporting the battery pack and the second main surface M2). Also, the set wire ST (see FIG. 9) may extend across the second main surface M2 having a free space formed above the second main surface M2, and the first sub-region A2-1 may be formed along the peripheral region AP of the insulating tape T disposed on the second main surface M2.

The adhesive Tb may be prevented from being exposed during cutting of the insulating tape T by the adhesive Tb that is located at a position retreating by the width of the first sub-region A2-1. The set wire ST (see FIG. 9) extending across the second main surface M2 of the battery cell 10 may be prevented from sticking by blocking leakage of the adhesive Tb from the insulating tape T. In embodiments of the present disclosure, the first sub-region A2-1 having weak adhesive strength or no adhesion may be formed entirely along the peripheral region AP of the insulating tape T. Also, the first sub-region A2-1 may be selectively formed only partially along the peripheral region AP of the insulating tape T. For example, along the peripheral region AP of the insulating tape T, the first sub-region A2-1 may be selectively formed only in the peripheral region AP formed on the second main surface M2 of the battery cell 10. For example, in embodiments of the present disclosure, if the first sub-region A2-1 is selectively formed along the peripheral region AP of the insulating tape T, the first sub-region A2-1 may be in the peripheral region AP on the second main surface M2, which is located relatively far from the terrace 10a of the battery cell 10, among the first and second main surfaces M1 and M2 of the battery cell 10.

In embodiments of the present disclosure as described above, the insulating tape T may cover at least a portion of the circuit unit 20 disposed on the electrode surface of the battery cell 10 (or the upper surface U of the battery cell 10). The insulating tape T may bypass (e.g., extend around) the circuit unit 20 disposed on the electrode surface of the battery cell 10 (or the upper surface U of the battery cell 10) and connect the first and second main surfaces M1 and M2 to each other, thereby covering at least a portion of the circuit unit 20. For example, referring to FIGS. 1-2, the insulating tape T may be connected to and extend from the first main surface M1 to be connected to and extend continuously to the second main surface M2, while extending over and overlapping a top of the circuit unit 20 at a surface between the first and second main surfaces M1 and M2. For example, the insulating tape T may extend, onto the second main surface M2 of the battery cell 10, from the first main surface M1 of the battery cell 10 or the terrace 10a at a position close to the first main surface M1 of the battery cell 10 across the circuit unit 20 on the terrace 10a. Also, the peripheral region AP of the insulating tape T may include a peripheral region AP on the first main surface M1 of the battery cell 10 or on the terrace 10a at a position close to the first main surface M1 of the battery cell 10, a peripheral region AP on the circuit unit 20 mounted on the terrace 10a, and a peripheral region AP on the second main surface M2 of the battery cell 10. The first sub-region A2-1 of the insulating tape T may be formed entirely along the insulating tape T (see FIG. 5A) or may be formed only in the peripheral region AP of the insulating tape T on the second main surface M2 of the battery cell 10 (see FIG. 5B). Also, the feature, in which the first sub-region A2-1 is formed only in the peripheral region AP of the insulating tape T on the second main surface M2 of the battery cell 10, may indicate that the first sub-region A2-1 may not be formed in the peripheral region AP of the insulating tape T attached to the first main surface M1 of the battery cell 10 or the terrace 10a at a position close to the first main surface M1 and in the peripheral region AP of the insulating tape T attached to the circuit unit 20 disposed on the terrace 10a.

In embodiments of the present disclosure, in the first sub-region A2-1 formed along the peripheral region AP of the insulating tape T, the adhesive Tb may be removed away from the irradiation position of laser beams during the laser cutting of cutting the insulating tape T from the tape base material TM (see FIG. 8), and thus, the adhesive Tb may be prevented from being exposed from the heat-shrunk tape base material TM (or the tape substrate Ta cut from the tape base material TM) through irradiation of the laser beams, which may prevent forming the physical interference with the set wire ST (see FIG. 9) or causing the adhesion noise with the set wire ST (see FIG. 9) due to the adhesive Tb that is exposed to the outside and leaks from the insulating tape T.

In embodiments of the present disclosure, the first sub-region A2-1 of the insulating tape T formed along the peripheral region AP of the insulating tape T may be defined by the tape substrate Ta and the adhesive Tb that is removed away from the edge of the tape substrate Ta by the width of the first sub-region region A2-1. For example, the insulating tape T may include the first region A1, which includes the tape substrate Ta and the adhesive Tb formed on the inner surface T1 of the tape substrate Ta, and the first sub-region A2-1, which includes the tape substrate Ta but does not include the adhesive Tb on the inner surface T1 of the tape substrate Ta, e.g., the tape substrate Ta without the adhesive Tb. The first sub-region A2-1 formed along the peripheral region AP of the insulating tape T and the first region A1 formed in the inner region AI of the insulating tape T may have different adhesive strengths. For example, the first sub-region A2-1 may be formed as a region in which the adhesive Tb is not provided, e.g., in which there is no adhesion. For example, the first sub-region A2-1 may be formed as a region in which adhesion is not provided, rather than a region having relatively weak adhesive strength. However, the first region A1 may be formed as a region having the adhesive Tb and exhibiting relatively strong adhesive strength.

Referring to FIG. 5A, in embodiments of the present disclosure, the second sub-region A2-2 of the insulating tape T may be formed in the isolated inner region AS, which is not connected to the peripheral region AP, in the inner region AI surrounded by the peripheral region AP. In embodiments of the present disclosure, the second sub-region A2-2, together with the first sub-region A2-1, may be formed as a region having relatively weak adhesive strength or as a region having no adhesion. However, as described above, the first sub-region A2-1 may be configured to solve the issue of adhesion to other surrounding components, such as the set wire ST (see FIG. 9) due to leakage of the adhesive Tb from the insulating tape T. For example, the adhesive Tb may be removed away from the irradiation position of laser beams in order to prevent the adhesive Tb from being exposed from the tape base material TM or the tape substrate Ta cut from the tape base material TM due to heat shrinkage as the insulating tape T is cut from the tape base material TM by the laser beams.

Unlike the first sub-region A2-1, the second sub-region A2-2 may include a region for generating weak adhesion to the integrated circuit chip IC or for removing the adhesion from the insulating tape T covering the circuit unit 20 with respect to the integrated circuit chip IC in a region in which the integrated circuit chip IC is located. For example, the second sub-region A2-2 may be formed at the position of the integrated circuit chip IC of the circuit unit 20 in the inner region AI of the insulating tape T, at which the insulating tape T attached to the circuit unit 20 mounted on the terrace 10a or on the electrode surface of the battery cell 10 (the upper surface U of the battery cell 10) is formed between the insulating tape T attached to the first main surface M1 or the terrace 10a at a position close to the first main surface M1 and the insulating tape T attached to the second main surface M2. For example, the integrated circuit chip IC may be formed in the isolated inner region AS of the insulating tape T which is not connected to the peripheral region AP of the insulating tape T. In general, corresponding to the position of the integrated circuit chip IC mounted on the circuit board 21 so as to be adjacent to the central position rather than both ends of the circuit board 21 in the longitudinal direction in the circuit unit 20, the second sub-region A2-2 may be formed in the isolated inner region AS surrounded by the peripheral region AP of the insulating tape T. For example, the integrated circuit chip IC may include switch elements, such as a field effect transistor (FET) for controlling the charging and discharging of the battery cell 10, or safety elements for controlling the charging and discharging of the battery cell 10. The insulating tape T may be detached due to lack of step coverage of the insulating tape T attached on a stepped portion protruding from the circuit board 21 forming the circuit unit 20, which may cause adhesion noise with the insulating tape T. Also, the adhesive Tb formed on the integrated circuit chip IC may act as a factor that interferes with heat dissipation of the integrated circuit chip IC on which heat is concentrated. In embodiments of the present disclosure, the second sub-region A2-2 having weak adhesive strength or no adhesive may be formed at a position corresponding to (e.g., covering or overlapping) the integrated circuit chip IC.

In embodiments of the present disclosure, the first sub-region A2-1 and the second sub-region A2-2 of the second region A2 may have an adhesive strength lower than the adhesive strength of the first region A1 formed in the inner region AI connected to the peripheral region AP, and may have no adhesive Tb rather than adjusting the adhesive strength. For example, considering the complexity of processes due to adjustment of the adhesive strength and the occurrence of adhesion noise due to low adhesive strength, the second region A2 including the first and second sub-regions A2-1 and A2-2 according to embodiments of the present disclosure may be formed as a region not having the adhesive Tb rather than as a region having the adhesive Tb that exhibits an adhesive strength lower than the adhesive strength of the first region A1.

In embodiments of the present disclosure as described above, the first sub-region A2-1 and the second sub-region A2-2 in the second region A2 may share, with the first region A1, the tape substrate Ta providing a common support base. The adhesive Tb may be removed from the second region A2 along the inner surface T1 of the tape substrate Ta. For example, the first and second sub-regions A2-1 and A2-2 of the second region A2 may include the tape substrate Ta without the adhesive Tb and may have substantially the same configuration.

FIG. 5C is a plan view of an insulating tape that may be applied to a battery pack according to embodiments of the present disclosure and shows the insulating tape in an unfolded state. For example, FIG. 5C is a plan view of an insulating tape according to modified embodiments of the insulating tape of FIG. 5A.

Referring to FIG. 5C, in some embodiments of the present disclosure, the first and second sub-regions A2-1 and A2-2 of the second region A2 may have different configurations. For example, the first sub-region A2-1 may include the tape substrate Ta without the adhesive Tb. Unlike the first sub-region A2-1, the second sub-region A2-2 may include an additional coating material CT that covers the adhesive Tb to remove the adhesion formed on the adhesive Tb. For example, the frit sub-region A2-1 may be configured such that the adhesive Tb retreats along the peripheral region AP of the tape substrate Ta that is cut by laser beams to prevent exposure of the adhesive Tb. Also, the first sub-region A2-1 may have a configuration in which the adhesive Tb is removed away from the irradiation position of laser beams and may include the tape substrate Ta from which the adhesive Tb has been removed, in order to prevent the adhesive Tb from being exposed from the heat-shrunk tape substrate Ta due to the input of laser heat. Considering limitations due to heat shrinkage of the tape substrate Ta, the exposure of the adhesive Tb may still potentially occur in the first sub-region A2-1 due to the heat shrinkage of the tape substrate Ta, even if additional other components are added onto the adhesive Tb formed on the inner surface T1 of the tape substrate Ta. For example, the first sub-region A2-1 may be formed from the tape substrate Ta without the adhesive Tb. In the second sub-region A2-2, unlike the first sub-region A2-1, the exposure of the adhesive Tb may be sufficiently prevented by removing the effect of the adhesive Tb. For example, the adhesion of the adhesive Tb may be removed by placing an additional component on the adhesive Tb.

Referring to FIG. 9, in embodiments of the present disclosure, the insulating tape T may bypass the circuit unit 20 to surround the circuit unit 20 and may extend in a direction of connection of the first main surface M1 of the battery cell 10 or the terrace 10a at a position relatively close to the first main surface M1 to the second main surface M2 of the battery cell 10. In embodiments of the present disclosure, the insulating tape T may have the first width W₁ formed on the first main surface M1 to cover the terrace 10a and the second width W₂ formed on the second main surface M2. Also, the first and second widths W₁ and W₂ may be designed to have different widths. For example, in embodiments of the present disclosure, the first and second widths W₁ and W₂ may satisfy the size relationship of the first width W₁>the second width W₂. For example, the battery pack according to embodiments of the present disclosure may be mounted in a set device such that the terrace 10a on the first main surface M1 of the battery cell 10 is at a lower position and the circuit unit 20 on the second main surface M2 of the battery cell 10 is at a higher position. In order to prevent electrical interference between a set device and the terrace 10a at a lower position in the set device, for example, to prevent electrical interference between the bottom surface of the mounting space of the battery pack and the terrace 10a at the lower position, a portion of the insulating tape T having the first width W₁ may be attached to the terrace 10a in the longitudinal direction. Also, a portion of the insulating tape T having the second width W₂, which is relatively less than the first width W₁ on the circuit unit 20, may be attached to the circuit unit 20. Also, the second width W₂ of the insulating tape T attached to the circuit unit 20 may extend relatively shorter than the first width W₁ of the insulating tape T attached to the terrace 10a, which may not interfere with the drawing of the input/output wire IO. For example, even if the input/output wire IO, which is drawn out through the relatively short second width W₂ of the input/output wire IO formed on the second main surface M2, folds toward the second main surface M2 of the battery cell 10 for connection to a connection terminal of the set device, adhesion between the input/output wire IO and the insulating tape T may be prevented.

In embodiments of the present disclosure, the peripheral region AP of the insulating tape T, in which the first sub-region A2-1 is formed, may include a cutting line CL of the insulating tape T, and the cutting line CL of the insulating tape T may be formed as a laser cutting line CL by the laser cutting of cutting the insulating tape T from the tape base material TM. For example, the insulating tape T may include an arrangement of the adhesive Tb that is away from the cutting line CL by the width of the first sub-region A2-1. Despite the tape base material TM (or the tape substrate Ta cut from the tape base material TM, see FIG. 8) due to the heat input of the laser cutting, the adhesive Tb may not be exposed from the tape base material TM or the tape substrate Ta cut from the tape base material TM. For example, despite the heat-shrunk tape base material TM (see FIG. 8) or the tape substrate Ta cut from the tape base material TM, an extra width as long as the width of the first sub-region A2-1 may remain from the residual tape base material TM due to heat shrinkage or from the tape substrate Ta cut from the tape base material TM.

According to the present disclosure, a battery pack is provided. During laser cutting for cutting the tape substrate, which forms the base of the insulating tape, from the tape base material corresponding to the raw material, even if heat shrinkage occurs in the tape base material or the tape substrate separated from the tape base material, the adhesive may be prevented from being exposed from the tape base material or the tape substrate separated from the tape base material. Also, unnecessary adhesion to the set wire extending across the insulating tape due to the adhesive exposed from the insulating tape may be prevented, and adhesion noise caused between the insulating tape and the set wire due to the exposed adhesive may be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A battery pack, comprising:
a battery cell including a first main surface and a second main surface facing each other;
a circuit unit on an upper surface of the battery cell, the upper surface of the battery cell connecting the first main surface and the second main surface of the battery cell to each other; and
an insulating tape extending from the first main surface to the second main surface of the battery cell while surrounding the circuit unit, the insulating tape including a first region and a second region having different adhesive strengths from each other.

2. The battery pack as claimed in claim 1, wherein the first region of the insulating tape has a stronger adhesive strength than the second region of the insulating tape.

3. The battery pack as claimed in claim 2, wherein:
the insulating tape includes:
a tape substrate defining a common base supporting the first region and the second region of the insulating tape, and
an adhesive layer on an inner surface of the tape substrate,
the first region of the insulating tape includes a first portion of the tape substrate and the adhesive layer, and
the second region of the insulating tape includes a second portion of the tape substrate without the adhesive layer.

4. The battery pack as claimed in claim 2, wherein the second region of the insulating tape is on a peripheral region of the insulating tape.

5. The battery pack as claimed in claim 4, wherein:
the second region of the insulating tape includes:
a first sub-region on the peripheral region of the insulating tape, and a second sub-region on an isolated inner region of the insulating tape, the second sub-region being spaced apart from the peripheral region of the insulating tape, and the first region of the insulating tape is on an inner region of the insulating tape connected to the peripheral region of the insulating tape.

6. The battery pack as claimed in claim 5, wherein:
the insulating tape includes:
a tape substrate defining a common base supporting the first region and the second region of the insulating tape, and
an adhesive layer on an inner surface of the tape substrate,
the first region of the insulating tape includes a first portion of the tape substrate and the adhesive layer on the inner surface of the tape substrate, and
the first sub-region and the second sub-region of the second region of the insulating tape have a same shape and including a second portion of the tape substrate without the adhesive layer.

7. The battery pack as claimed in claim 5, wherein:
the insulating tape includes:
a tape substrate defining a common base supporting the first region and the second region of the insulating tape, and
an adhesive layer on an inner surface of the tape substrate,
the first region of the insulating tape includes a first portion of the tape substrate and the adhesive layer on the inner surface of the tape substrate, and
the first sub-region and the second sub-region of the second region of the insulating tape have different shapes from each other.

8. The battery pack as claimed in claim 7, wherein:
the first sub-region of the second region of the insulating tape includes a second portion of the tape substrate without the adhesive layer, and
the second sub-region of the second region of the insulating tape includes a coating material covering the adhesive layer to remove adhesiveness.

9. The battery pack as claimed in claim 5, wherein the first region of the insulating tape is on the inner region of the insulating tape surrounding the second sub-region of the second region of the insulating tape, the first region being connected to the peripheral region of the insulating tape.

10. The battery pack as claimed in claim 5, wherein the insulating tape further includes a cutting line along an outer edge thereof, the cutting line extending along the peripheral region of the insulating tape that includes the first sub-region of the second region of the insulating tape.

11. The battery pack as claimed in claim 10, wherein the cutting line is formed by laser cutting.

12. The battery pack as claimed in claim 10, wherein the insulating tape includes a tape substrate and an adhesive layer on an inner surface of the tape substrate, the adhesive layer being spaced apart from the cutting line by a width of the first sub-region of the second region.

13. The battery pack as claimed in claim 5, wherein the first sub-region of the second region of the insulating tape extends along an entirety of the peripheral region of the insulating tape, the first sub region surrounding an entire outline of the insulating tape.

14. The battery pack as claimed in claim 5, wherein:
the battery cell further includes a terrace defining a mounting space, the circuit unit being mounted on the mounting space of the terrace,
on a basis of a direction in which the first main surface and the second main surface face each other, the first main surface is located at a position relatively close to the terrace and the second main surface is located at a position relatively far from the terrace, and
the first sub-region of the second region of the insulating tape is at least on a portion of the peripheral region of the insulating tape that is attached to the second main surface of the battery cell.

15. The battery pack as claimed in claim 14, wherein the first sub-region of the second region is not on a portion of the peripheral region of the insulating tape that is attached to the first main surface, the terrace, or the circuit unit.

16. The battery pack as claimed in claim 14, wherein the insulating tape extends in a direction of connection of the first main surface or the terrace at a position relatively close to the first main surface to the second main surface, while bypassing the circuit unit to surround the circuit unit.

17. The battery pack as claimed in claim 16, wherein the insulating tape includes:
a first width covering the terrace on the first main surface; and
a second width covering the second main surface, the first width being larger than the second width.

18. The battery pack as claimed in claim 17, wherein:
the circuit unit includes a circuit board and an input/output wire drawn from the circuit board to an outside of the circuit board, and
the input/output wire extends beyond the circuit board at a position outside the second width of the insulating tape covering the circuit board on the second main surface of the battery cell, the input/output wire not contacting the insulating tape.

19. The battery pack as claimed in claim 5, wherein the circuit unit includes a circuit board and an integrated circuit chip on the circuit board, the second sub-region of the second region of the insulating tape being at a position corresponding to the integrated circuit chip.
